(19) United States
(12) Patent Application Publication
(10) Pub. No.: US 2025/0207954 A1
(43) Pub. Date: Jun. 26, 2025

(54) MONITORING SYSTEM BASED ON MULTIPLEXED MULTIMODE INTERFEROMETRIC SENSORS

(71) Applicant: UNIVERSITY OF PITTSBURGH-OF THE COMMONWEALTH SYSTEM OF HIGHER EDUCATION, PITTSBURGH, PA (US)

(72) Inventors: Paul R. Ohodnicki, Jr., Allison Park, PA (US); Nageswara Rao Lalam, Pittsburgh, PA (US); Ruishu Wright, Venetia, PA (US); Khurram Naeem, Pittsburgh, PA (US); Dolendra Karki, Pittsburgh, PA (US)

(73) Assignee: UNIVERSITY OF PITTSBURGH-OF THE COMMONWEALTH SYSTEM OF HIGHER EDUCATION, PITTSBURGH, PA (US)

(21) Appl. No.: 18/851,112

(22) PCT Filed: Apr. 4, 2023
(86) PCT No.: PCT/US2023/065301

§ 371 Date: Sep. 26, 2024

Related U.S. Application Data
(60) Provisional application No. 63/362,428, filed on Apr. 4, 2022.

(51) Int. Cl. G01D 5/353; G01H 9/00; G01K 11/32; G01R 33/032

(52) U.S. Cl. CPC G01D 5/35332; G01H 9/004; G01K 11/32; G01R 33/032

(57) ABSTRACT

An optical fiber-based monitoring system and associated method includes a light source structured and configured for generating a first light signal, one or more multimode interferometric fiber structures, such as an SMS or SMSMS fiber structure, structured and configured to receive the first light signal and output an output light signal indicative of a parameter associated with the multimode interferometric fiber structure, and a photodetector coupled to an output of multimode interferometric fiber structure for converting the output light signal into an electrical signal.

### STATEMENT OF GOVERNMENT INTEREST

This invention was made with government support under grant #s DE-AR0001332 and DE-NE0009210 awarded by the Department of Energy (DOE). The government has certain rights in the invention.

### FIELD OF THE INVENTION

The present invention pertains to optical fiber-based monitoring systems for monitoring a parameter such as, without limitation, vibration/acoustic emission, temperature, chemistry (e.g., H₂, CO₂), magnetic field, etc., and, in particular, to a monitoring system based on a multiplexed multimode interferometric structure such as a single-mode-multimode-single-mode (SMS) fiber sensor structure such as, without limitation, a single-mode-no-core-single-mode (SNS) fiber structure or, alternatively, a single-mode-multimode-single-mode-multimode-single-mode (SMSMS) fiber structure.

### BACKGROUND OF THE INVENTION

Sensing plays an important role in many areas such as public safety, scientific, and commercial applications, including energy infrastructures, pipelines, seismology, aviation, transportation, non-destructive evaluation, machinery, wildlife, perimeter security, and flow monitoring. For example, vibration/acoustic emission monitoring is widely used for many of these applications. Among various vibration/acoustic sensors, fiber optic-based sensing has gained lots of attention due to the small size (˜250 μm diameter), light weight, easy installation, remote measurement capability, high sensitivity, immunity to electromagnetic interference, resistance to corrosion, and harsh environmental capability of such sensors. Fiber optic sensors based on fiber Bragg gratings (FBG), Sagnac, Fabry-Perot interferometer, and Mach-Zehnder interferometer (MZI) structures have been proposed and demonstrated. However, the fabrication and processing of these sensors are difficult and complex, and the resulting sensors have low sensitivity. For instance, the fabrication of FBG sensors requires expensive equipment such as an excimer laser or CO2 laser, which results in the sensor systems being more complex and expensive. Moreover, such fiber sensors rely on the demodulation of external vibration and acoustic emission induced peak wavelength shifts, which need a relatively long time to obtain a steady-state spectrum. Therefore, spectral shift detection with a slow response time is not suitable for sensing rapidly and dynamically changing environments. Furthermore, the above fiber structures also have a limited signal-to-noise ratio (SNR).

There is thus room for improvement in the field of optical fiber-based sensors and sensing systems. In particular there is room for improvement in vibration and acoustic emission sensors.

### SUMMARY OF THE INVENTION

In one embodiment, an optical fiber-based monitoring system is provided that includes a light source structured and configured for generating a first light signal, a multimode interferometric fiber structure, such as an SMS or SMSMS fiber structure, that is configured to receive the first light signal and output an output light signal indicative of a parameter associated with the multimode interferometric fiber structure, and a photodetector coupled to an output of multimode interferometric fiber structure for converting the output light signal into an electrical signal.

In another embodiment, an optical fiber-based monitoring method is provided that includes generating a first light signal, receiving the first light signal in a multimode interferometric fiber structure, such as an SMS or SMSMS fiber structure, and outputting an output light signal indicative of a parameter associated with the multimode interferometric fiber structure, and converting the output light signal into an electrical signal.

In yet another particular embodiment, an optical fiber-based monitoring system, is provided that includes a light source structured and configured for generating a first light signal, a coupler coupled to the light source for receiving the first light signal, and a fiber structure assembly coupled to the coupler for receiving the first light signal. The fiber structure assembly in this particular embodiment includes a plurality of multimode interferometric fiber structures, such as SMS fiber structures, that are coupled in a manner such the first light signal will be received by each of the multimode interferometric fiber structures, and wherein each of the multimode interferometric fiber structures is configured to output an output light signal indicative of a parameter associated with the multimode interferometric fiber structure. One or more photodetectors are coupled to the fiber structure assembly for converting each output light signal. In one particular implementation, the system further includes an optical switch coupled to the fiber structure assembly, the optical switch being structured and configured to selectively and individually connect to an output of each of the multimode interferometric fiber structures as a function of time such that the optical switch outputs only a selected one of the output signals at any one time. In this implementation, the system includes a photodetector coupled to an output of the optical switch for converting the selected one of the output signals currently being output by the optical switch into an electrical signal.

In still another embodiment, an optical fiber-based monitoring method is provided. The method includes generating a first light signal, receiving the first light signal in a fiber structure assembly that includes a plurality of multimode interferometric fiber structures that are coupled in a manner such that first light signal is received by each one of the multimode interferometric fiber structures, wherein each of the fiber structures is configured to output an output light signal indicative of a parameter associated with the multimode interferometric fiber structure. The method also includes converting each of the output signals into an electrical signal, for example and without limitation, sequentially using an optical switch.

### BRIEF DESCRIPTION OF THE DRAWINGS

FIG. 1 is a schematic diagram of a vibration monitoring system according to an exemplary embodiment of the disclosed concept;

FIG. 2 is a schematic diagram of an SNS fiber structure according to an exemplary embodiment of the disclosed concept;

FIG. 3 is a schematic diagram of a vibration or acoustic emission monitoring system according to an alternative exemplary embodiment of the disclosed concept;

FIG. 4 is a schematic diagram of an SMSMS fiber structure according to another exemplary embodiment of the disclosed concept;

FIG. 5 is a schematic illustration of an exemplary SMSMS fiber structure and a test set up for measuring acoustic frequency response;

FIG. 6 is a schematic diagram of a fiber optic cable sensing device according to a particular embodiment of the disclosed concept;

FIG. 7 is a schematic diagram of a fiber optic cable sensing device according to a another particular embodiment of the disclosed concept; and

FIG. 8 is a schematic diagram of a fiber optic cable sensing device according to a yet another particular embodiment of the disclosed concept.

### DETAILED DESCRIPTION

As used herein, the singular form of “a”, “an”, and “the” include plural references unless the context clearly dictates otherwise.

As used herein, the statement that two or more parts or components are “coupled” shall mean that the parts are joined or operate together either directly or indirectly, i.e., through one or more intermediate parts or components, so long as a link occurs.

As used herein, the term “directly coupled” means that two elements are directly in contact with each other.

As used herein, the term “number” shall mean one or an integer greater than one (i.e., a plurality).

As used herein, the term “controller” shall mean a programmable analog and/or digital device (including an associated memory part or portion) that can store, retrieve, execute and process data (e.g., software routines and/or information used by such routines), including, without limitation, a field programmable gate array (FPGA), a complex programmable logic device (CPLD), a programmable system on a chip (PSOC), an application specific integrated circuit (ASIC), a microprocessor, a microcontroller, a programmable logic controller, or any other suitable processing device or apparatus. The memory portion can be any one or more of a variety of types of internal and/or external storage media such as, without limitation, RAM, ROM, EPROM(s), EEPROM(s), FLASH, and the like that provide a storage register, i.e., a non-transitory machine readable medium, for data and program code storage such as in the fashion of an internal storage area of a computer, and can be volatile memory or nonvolatile memory.

As used herein, the term “no-core fiber” or “NCF” shall mean an optical fiber in which there is no core/cladding structure such that the medium surrounding the fiber serves as the effective cladding.

As used herein, the term “single-mode fiber” or “SMF” shall mean an optical fiber in which a dominant single propagating mode is guided within the fiber (even if additional modes are present).

As used herein, the term “multi-mode fiber” or “MMF” shall mean an optical fiber in which numerous (i.e., a plurality of) modes are guided within the fiber. An NCF is one non-limiting example of an MMF.

As used herein, the term “single-mode-no-core-single mode (SNS) fiber structure” shall mean a fiber optic structure that includes a no-core fiber that is provided between and directly or indirectly coupled to two single-mode fibers at opposite ends of the no-core fiber such that an optical path is created from one single-mode fiber to the other single-mode fiber through the no-core fiber. An SNS fiber structure is one non-limiting example of an SMS fiber structure. An example of an SNS fiber structure is provided in FIG. 2.

As used herein, the term “single-mode-multi-mode-single mode (SMS) fiber structure” shall mean a fiber optic structure that includes a multi-mode fiber that is provided between and directly or indirectly coupled to two single-mode fibers at opposite ends of the multi-mode fiber such that an optical path is created from one single-mode fiber to the other single-mode fiber through the multi-mode fiber.

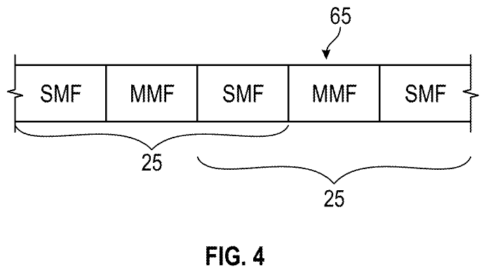

As used herein, the term “single-mode-multi-mode-single-mode-multi-mode-single-mode (SMSMS) fiber structure” shall mean a fiber optic structure that includes a first single-mode fiber, a first multi-mode fiber having a first end coupled directly or indirectly to an end of the first single-mode fiber, a second single-mode fiber having a first end coupled directly or indirectly to a second end of the first multi-mode fiber, a second multi-mode fiber having a first end coupled directly or indirectly to a second end of the second single-mode fiber, and a third single-mode fiber coupled to a second end of the second-multi-mode fiber. An SMS SNS fiber structure is thus is part of an SMSMS SNS fiber structure. An example of an SMSMS fiber structure is provided in FIG. 4.

As used herein, the term “quasi-distributed measurement” shall mean measurements of sensor elements at a plurality of distinct locations to allow for measuring parameters both temporally and in a spatially distributed manner.

Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

The disclosed concept will now be described, for purposes of explanation, in connection with numerous specific details in order to provide a thorough understanding of the subject invention. It will be evident, however, that the disclosed concept can be practiced without these specific details without departing from the spirit and scope of this innovation.

As described in detail herein, the disclosed concept provides a simple, low-cost, and highly-sensitive vibration/acoustic emission sensor based on an SMS fiber structure or SMSMS fiber structure with multiplexing/quasi-distributed measurement capability. In one particular exemplary embodiment described in detail herein, the fiber structure is an SMS fiber structure that is an SNS fiber structure, or an SMSMS fiber structure that includes an SNS fiber structure. The disclosed concept has several advantages including increased sensitivity by employing a multi-mode fiber, such as a no-core fiber, and enabling quasi-distributed measurement capability by utilizing a multiplexing technique using several SMS (e.g., SNS) or SMSMS fiber structures. The method of the disclosed concept thus enables cost-effective measurement, low complexity, and enhanced sensitivity, while at the same time producing great economic impact.

It is contemplated that the disclosed concept may be used in a wide variety of quasi-distributed dynamic acoustic/vibration sensing applications, including, without limitation: (1) pipeline monitoring, (2) energy infrastructure monitoring, (3) wellbore integrity monitoring, (4) perimeter security monitoring in, for example, military applications, (5) transportation (rail, road, port, or airport) industry monitoring, (6) industrial plant monitoring, (7) subsea and earthquake monitoring, and (8) smart city applications. Through integration of the SMS or SMSMS sensor with additional sensing materials, described in greater detail below, it is also contemplated that the concept may be used in chemical (e.g., H₂, CO₂, CH₄, pH) and magnetic field or current sensing applications. Examples of sensing materials could include, without limitation, chemically sensitive layers with associated refractive index changes as a function of gas or solution phase chemistry, magnetic field, etc. and including but not limited to metalorganic framework materials, metal oxides, metal nanoparticle incorporated oxides, metal nanoparticle incorporated polymers, fluids with colloidal nanoparticles, metallic films, etc.

In the disclosed concept, the sensor includes a short section of MMF, e.g., NCF in the exemplary embodiment, which is sandwiched between two SMFs to form an SMS structure or to form a part of an SMSMS structure. These configurations offer some unique advantages, such as ease of fabrication, low cost, flexible design, and high sensitivity, all of which are useful advantages in the development of real-world sensors. When light is injected into the MMF section through the lead-in SMF, multiple modes will be excited and then propagate with interference along the MMF section with their corresponding propagation constants. At the second interface, the multiple modes are coupled into the lead-out SMF. The output power at the lead-out SMF is determined by the mode interference between the various modes in the MMF (e.g., NCF) and the coupling between the MMF and lead-out SMF, which is significantly dependent on the physical properties of the MMF section.

As noted herein, the sensor may be a vibration or an acoustic emission sensor. In such a case, if the MMF (e.g., NCF) section experiences vibration or acoustic emission, the fiber undergoes fiber length change by a tensile and compressive strain, hence altering the output intensity. As a result, the SMS (e.g., SNS in the exemplary embodiment) or SMSMS fiber transmission spectrum will periodically change to blue-shift or red-shift. More specifically, the subject sensor is called a multimode interferometric structure, which means that there are interference fringes within the broadband optical spectrum. These fringes will shift to shorter or longer wavelength as the MMF (e.g., NCF) segment increases or decreases in length, respectively. These shifted fringes correspond to the blue shift and red shift. Therefore, at a certain vibration or acoustic emission frequency, the resultant spectrum intensity increases and decreases with time.

By demodulating the vibration/acoustic emission induced intensity fluctuations, the vibration signals can be quantified in real-time. One method for demodulation that may be employed in connection with the disclosed concept is to measure the intensity fluctuations in real-time and then use a Fourier transform of the measured signal in order to derive the amplitude of the spectral content as a function of frequency. This Fourier transform can be performed in real-time to allow for monitoring and tracking of the frequency content of the signal, which can then be correlated to specific information content of the vibration and the acoustic signal. This frequency content can be used to infer information about specific physical phenomena that the disclosed concept is seeking to detect and quantify using the sensor.

As also noted herein, the sensor may also be a temperature, chemistry, magnetic field, electric field or current sensor. Exemplary implementations of sensors of these types are described in greater detail herein.

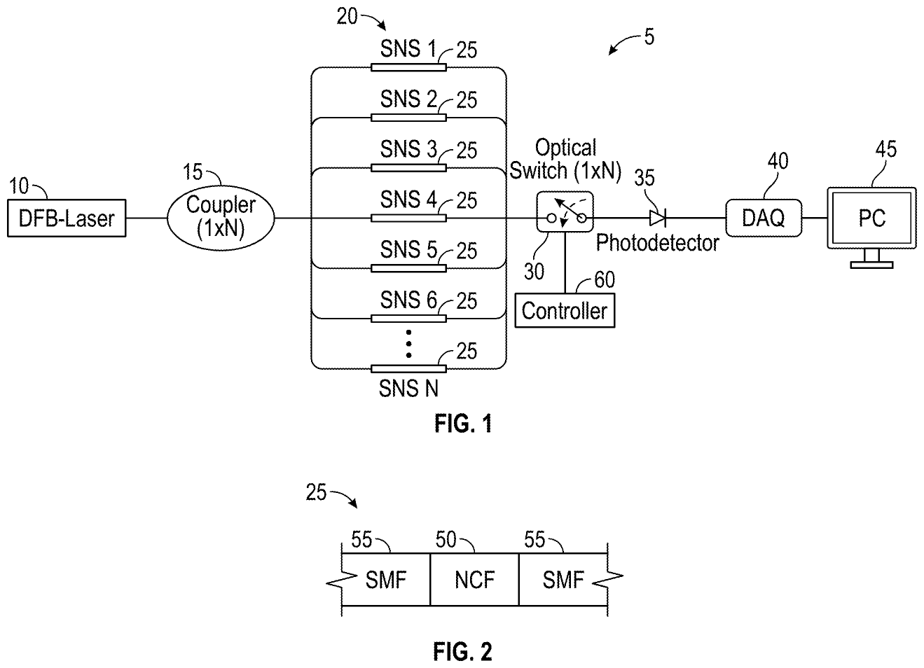

FIG. 1 is a schematic diagram of a vibration/acoustic emission monitoring system 5 according to an exemplary embodiment of the disclosed concept. As seen in FIG. 1, vibration/acoustic emission monitoring system 5 includes a distributed feedback (DFB) laser 10 as a laser source (e.g., with an output power of 45 mW), a 1×N fiber coupler 15 coupled to the output of DFB laser 10, and a fiber structure assembly 20 coupled to the outputs of 1×N fiber coupler 15. Fiber structure assembly 20 includes a plurality of (i.e., N) SMS fiber structures coupled in a manner such each of the N outputs of 1×N fiber coupler 15 is coupled to a respective one of the SMS fiber structures 25.

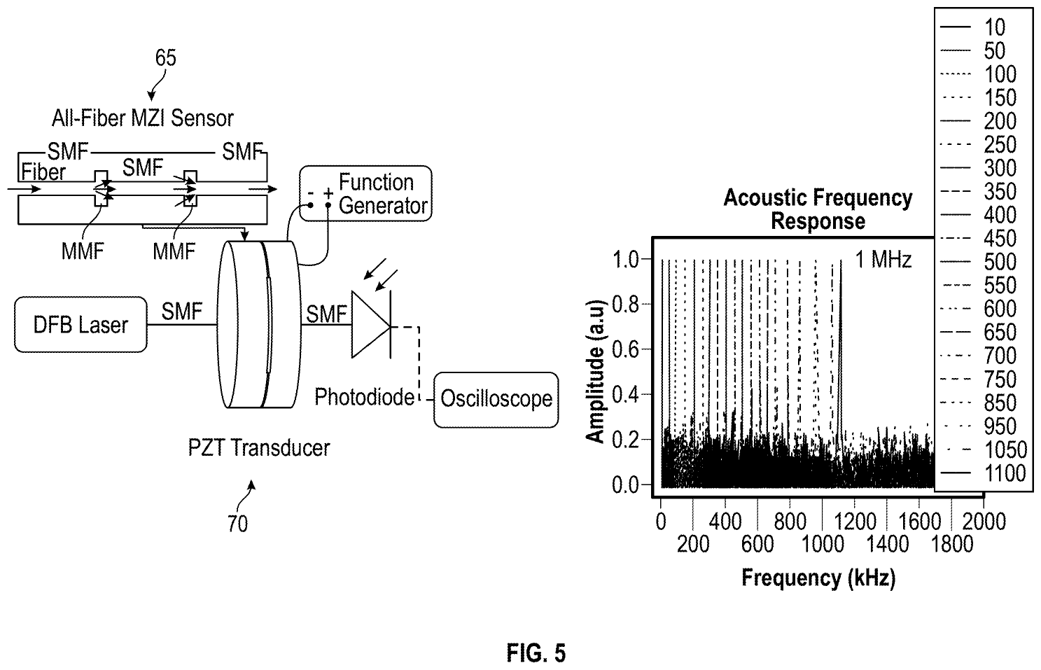

In the non-limiting exemplary embodiment shown in FIG. 1, each SMS fiber structure 25 is an SNS fiber structure as shown in FIG. 2. As seen in FIG. 2, in the exemplary embodiment, the SMS fiber structures 25 in the form of SNS fiber structures are each formed by splicing a section 50 (e.g., a 5 cm long section) of NCF between two pieces of standard SMF 55. A customized core alignment fusion splicing program with appropriate fusion current and fusion time may be employed to line up the fibers to minimize the splice loss. It will be appreciated that employing SNS fiber structures as the SMS fiber structures 25 is meant to be exemplary only, and that other SMS fiber structures may also be employed. Alternatively, each SMS fiber structure 25 may be part of a, SMSMS fiber structure 65 as shown in FIG. 4. FIG. 5 illustrates the acoustic frequency response of an exemplary SMSMS fiber structure 65 as measured by a test set-up 70 that includes a DFB laser, a function generator coupled ot a PZT transducer, a photodiode, and an oscilloscope.

Referring again to FIG. 1, vibration/acoustic emission monitoring system 5 further includes a 1×N optical switch 30, a high-speed photodetector 35, a data acquisition (DAQ) unit 40 and a PC 45 with data processing software, such as LABVIEW™ software. In particular, the output of each SMS fiber structure 25 is coupled to a respective one of the N inputs of 1×N optical switch 30. In the exemplary embodiment, 1×N optical switch 30 is a fast (e.g., 15 ms) optical switch that connects to the various fiber paths or channels by a micro-mechanical fiber to fiber auto-alignment platform that is activated via an electrical relay technique under the control of computer software running on a controller 60 provided as part of vibration/acoustic emission monitoring system 5. High-speed photodetector 35 is coupled to the single output of 1×N optical switch 30, and the output of high-speed photodetector 35 is coupled to the input of DAQ 40 and ultimately to PC 45.

In operation, the single wavelength output of DFB laser 10 is split into N paths by 1×N fiber coupler 15. As a result, single wavelength output of DFB laser 10 is provided to each of the SMS fiber structures 25. Optical switch 30 is used to cycle the optical interrogation between the individual samples (the individual SMS fiber structures 25) as a function of time. At each point in the cycling, the output of the connected SMS fiber structure 25 is provided to photodetector 35 and then to DAQ 40 and PC 45 for processing. In the exemplary embodiment, the sensor elements are placed at different locations in the environment to be monitored, and so in this way the array of sensors works as a “quasi-distributed” sensor array.

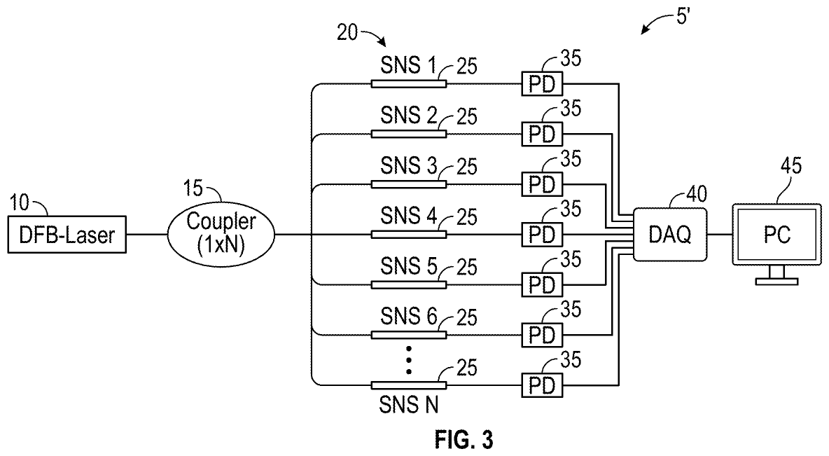

FIG. 3 is a schematic diagram of a vibration/acoustic emission monitoring system 5′ according to an exemplary embodiment of the disclosed concept. Vibration/acoustic emission monitoring system 5′ is similar to vibration/acoustic emission monitoring system 5, and like parts are labelled with like reference numerals. However, in vibration/acoustic emission monitoring system 5′, rather than having a single photodetector 35 and 1×N optical switch 30, it includes N photodetectors 35, each one couple to a respective one of the SMS fiber structures 25, with the outputs of the photodetectors 35 being provided to DAQ 40.

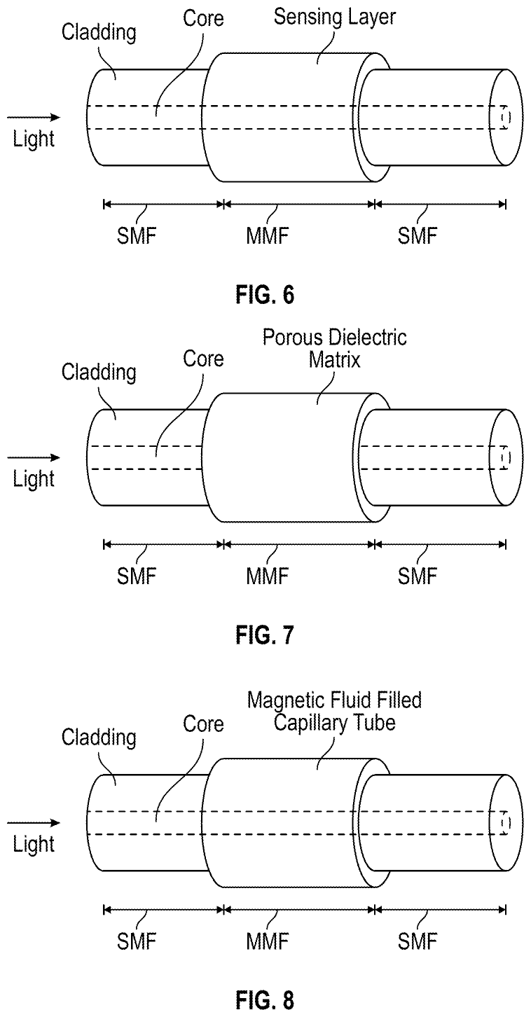

The disclosed concept may also be realized and extended to temperature, chemical (e.g., H₂, CO₂, CH₄, pH), magnetic field, current and/or other measurements by coating the MMF (e.g., NCF) with a nanocomposite thin-film(s), sorbent films, catalysts, or other class of sensing layers as shown schematically in FIG. 6, such as, without limitation, metal nanoparticle incorporated polymer or dielectric films, magnetic nanoparticles embedded in a fluid, magnetic nanoparticles embedded within a polymer or dielectric, metalorganic framework films, metal nanoparticle incorporated framework films, zeolites, metal nanoparticle incorporated zeolite films, magnetic oxides, conducting oxides, metallic films, etc., and monitoring the temperature and/or electromagnetic field and/or chemical (gas, liquid) induced optical transmission change. More specifically, the sensing materials that are applied to the MMF (e.g., NCF) segment to modify the transmission intensity in addition to the interferometric affects which are responsible for the acoustic/vibration signals. If the sensing material responds to temperature, or another parameter (magnetic field, chemistry, gas, etc.), then the SMS fiber structure 25 can be a multifunctional sensor element and/or can be used to monitor these alternative parameters. In addition to refractive index changes of a sensing layer, strain responses may also be transduced by the SMS or SMSMS structures in which the strain of the sensing layer responds to the analyte of interest producing a shift in the spectral intensity and wavelength dependence of the sensor. Also, multiple SMS sensors of unique construction and/or functionalization with sensing layers may be multiplexed in order to realize a multiparameter sensing array.

In one particular exemplary embodiment, shown schematically in FIG. 7, an H₂ sensor can be formed by coating the MMF of an SMS (shown) or SMSMS structure with a nanocomposite coating layer comprising metallic nanoparticles physisorbed in a porous dielectric matrix, such as a porous polymer or a metal organic framework (MOF). In the non-limiting exemplary embodiment, the metallic nanoparticles may include precious/noble metal nanoparticles, such as Au, Pd, Pt or associated alloy nanoparticles.

In another particular exemplary embodiment, shown schematically in FIG. 8, a magnetic field sensor can be formed by coating the MMF of an SMS (shown) or SMSMS structure with a nanocomposite coating layer comprising colloidal single domain magnetic nanoparticles (e.g., Fe3O4, γ-Fe2O3) in a liquid carrier (e.g., kerosene, heptane, water). The magnetic nanoparticles and the liquid carrier may be held within a capillary tube coupled to the fiber as shown in FIG. 8. In an exemplary embodiment, the colloidal single domain magnetic nanoparticles are dispersed in the liquid carrier with the aid of surfactants (e.g., oleic acid-kerosene, lauric acid-water) for homogeneous In another exemplary embodiment, the nanoparticles have diameters of ˜5-10 nm. In further alternative embodiments, the coating/sensing layer may be made of a magneto-optical, magneto-resistive, or magneostrictive material.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

What is claimed is:

1. An optical fiber-based monitoring system, comprising:
a light source structured and configured for generating a first light signal;
a fiber structure assembly including a number of multimode interferometric fiber structures, each of the multimode interferometric fiber structures being configured to receive the first light signal and to output an output light signal indicative of a parameter associated with the multimode interferometric fiber structure; and
a number of photodetectors coupled the fiber structure assembly for converting each output light signal into an electrical signal.

2. The optical fiber-based monitoring system according to claim 1, wherein each of a number of the multimode interferometric fiber structures includes an SMS fiber structure.

3. The optical fiber-based monitoring system according to claim 2, wherein a number of the SMS fiber structures are part of an SMSMS fiber structure.

4. The optical fiber-based monitoring system according to claim 1, wherein the number of multimode interferometric fiber structures is a plurality of multimode interferometric fiber structures, the system including a coupler coupled to the light source for receiving the first light signal and providing the first light signal to each of the multimode interferometric fiber structures.

5. The optical fiber-based monitoring system according to claim 2, further comprising an optical switch coupled to the fiber structure assembly, the optical switch being structured and configured to selectively and individually connect to an output of each of the SMS fiber structures as a function of time such that the optical switch outputs only a selected one of the output signals at any one time, wherein the photodetector is a single photodetector coupled to an output of the optical switch for converting the selected one of the output signals currently being output by the optical switch into an electrical signal.

6. The optical fiber-based monitoring system according to claim 4, wherein the photodetector is a plurality of photodetectors, each photodetector being coupled to an output of respective one of the SMS fiber structures.

7. The optical fiber-based monitoring system according to claim 2, wherein each of the SMS fiber structures is an SNS fiber structure.

8. The optical fiber-based monitoring system according to claim 2, wherein for each of the SMS fiber structures, the parameter associated with the SMS fiber structure is vibration or acoustic emission being experienced by the SMS fiber structure which will cause a length of the SMS fiber structure to change, wherein the electrical signal is a vibration or acoustic emission signal, and wherein the optical fiber-based monitoring system further includes a computing system structured and configured to demodulate vibration or acoustic emission induced intensity fluctuations in the vibration or acoustic emission signal and quantify the vibration or acoustic emission signal in real-time.

9. The optical fiber-based monitoring system according to claim 2, wherein for each of the SMS fiber structures, the parameter associated with the SMS fiber structure is temperature being experienced by the SMS fiber structure, wherein the electrical signal comprises a temperature signal, and wherein the optical fiber-based monitoring system further includes a computing system structured and configured to demodulate temperature induced intensity fluctuations in the temperature signal and quantify the temperature signal in real-time.

10. The optical fiber-based monitoring system according to claim 2, wherein each of the SMS fiber structures is coated with a temperature sensitive sensing material, wherein for each of the SMS fiber structures, the parameter associated with the SMS fiber structure is temperature being experienced by the SMS fiber structure, wherein the electrical signal comprises a temperature signal, and wherein the optical fiber-based monitoring system further includes a computing system structured and configured to demodulate temperature induced intensity fluctuations in the temperature signal and quantify the temperature signal in real-time.

11. The optical fiber-based monitoring system according to claim 10, wherein the temperature sensitive sensing material comprises a nanocomposite thin-film.

12. The optical fiber-based monitoring system according to claim 2, wherein each of the SMS fiber structures is coated with a parameter sensitive sensing material, wherein for each of the SMS fiber structures, the parameter associated with the SMS fiber structure is one of magnetic field strength, chemical composition or gas concentration in a vicinity of the SMS fiber structure, wherein the electrical signal comprises a parameter signal, and wherein the optical fiber-based monitoring system further includes a computing system structured and configured to demodulate parameter induced intensity fluctuations in the parameter signal and quantify the parameter signal in real-time.

13. The optical fiber-based monitoring system according to claim 12, wherein the parameter associated with the SMS fiber structure is H₂ concentration, and wherein the parameter sensitive sensing material includes a nanocomposite coating layer comprising metallic nanoparticles in a porous dielectric matrix.

14. The optical fiber-based monitoring system according to claim 13, wherein the porous dielectric matrix is a porous polymer or a metal organic framework (MOF).

15. The optical fiber-based monitoring system according to claim 13, wherein the metallic nanoparticles include precious/noble metal nanoparticles.

16. The optical fiber-based monitoring system according to claim 15, wherein the nanoparticles are Pd, Pt, Au, or Ag nanoparticles.

17. The optical fiber-based monitoring system according to claim 12, wherein the parameter associated with the SMS fiber structure is magnetic field strength, and wherein the parameter sensitive sensing material includes a nanocomposite coating layer comprising colloidal single domain magnetic nanoparticles dispersed in a liquid carrier.

18. The optical fiber-based monitoring system according to claim 17, wherein the colloidal single domain magnetic nanoparticles are Fe3O4 or γ-Fe2O3.

19. The optical fiber-based monitoring system according to claim 17, wherein the liquid carrier is kerosene, heptane, or water.

20. The optical fiber-based monitoring system according to claim 17, wherein the colloidal single domain magnetic nanoparticles are dispersed in the liquid carrier with the aid of a surfactant for homogeneous dispersion.

21. The optical fiber-based monitoring system according to claim 20, wherein the surfactant is oleic acid or lauric acid.

22. The optical fiber-based monitoring system according to claim 12, wherein the parameter associated with the SMS fiber structure is magnetic field strength, and wherein the parameter sensitive sensing material includes a magneto-optical material, a magnetoresistive material, or a magnetostrictive material.

23. The optical fiber-based monitoring system according to claim 1, wherein the light source is a DFB laser having a single wavelength output.

24. The optical fiber based monitoring system according to claim 2, wherein each of the SMS fiber structures is positionable at a distinct location to allow for quasi-distributed measurement both temporally and in a spatially distributed manner.

25. An optical fiber-based monitoring method, comprising:
generating a first light signal;
receiving the first light signal in a fiber structure assembly that includes a number of multimode interferometric fiber structures that are coupled in a manner such that each of the multimode interferometric fiber structures is configured to receive the first light signal and output an output light signal indicative of a parameter associated with the multimode interferometric fiber structure;
converting each of the output signals into an electrical signal.

26. The optical fiber-based monitoring method according to claim 25, wherein each of a number of the multimode interferometric fiber structures includes an SMS fiber structure.

27. The optical fiber-based monitoring method according to claim 26, wherein a number of the SMS fiber structures are part of an SMSMS fiber structure.

28. The optical fiber-based monitoring method according to claim 26, wherein the number of multimode interferometric fiber structures is a plurality of multimode interferometric fiber structures.

29. The optical fiber-based monitoring method according to claim 28, wherein the converting comprises selectively and individually connecting to an output of each of the SMS fiber structures as a function of time to provide only a selected one of the output signals at any one time, and converting the selected one of the output signals currently being output into an electrical signal.

30. The optical fiber-based monitoring method according to claim 26, wherein each of the SMS fiber structures is an SNS fiber structure.

31. The optical fiber-based monitoring method according to claim 26, wherein for each of the SMS fiber structures, the parameter associated with the SMS fiber structure is vibration or acoustic emission being experienced by the SMS fiber structure which will cause a length of the SMS fiber structure to change, wherein the electrical signal is a vibration or acoustic emission signal, and wherein the method further includes demodulating vibration or acoustic emission induced intensity fluctuations in the vibration or acoustic emission signal and quantifying the vibration or acoustic emission signal in real-time.

32. The optical fiber-based monitoring method according to claim 26, wherein for each of the SMS fiber structures, the parameter associated with the SMS fiber structure is temperature being experienced by the SMS fiber structure, wherein the electrical signal comprises a temperature signal, and wherein the optical fiber-based monitoring system further includes a computing system structured and configured to demodulate temperature induced intensity fluctuations in the temperature signal and quantify the temperature signal in real-time.

33. The optical fiber-based monitoring method according to claim 26, wherein each of the SMS fiber structures is coated with a temperature sensitive sensing material, wherein for each of the SMS fiber structures, the parameter associated with the SMS fiber structure is temperature being experienced by the SMS fiber structure, wherein the electrical signal comprises a temperature signal, and wherein the method further includes demodulating temperature induced intensity fluctuations in the temperature signal and quantifying the temperature signal in real-time.

34. The optical fiber-based monitoring method according to claim 33, wherein the temperature sensitive sensing material comprises a nanocomposite thin-film.

35. The optical fiber-based monitoring method according to claim 26, wherein each of the SMS fiber structures is coated with a parameter sensitive sensing material, wherein for each of the SMS fiber structures, the parameter associated with the SMS fiber structure is one of magnetic field strength, chemical composition or gas concentration in a vicinity of the SMS fiber structure, wherein the electrical signal comprises a parameter signal, and wherein the method further includes demodulating parameter induced intensity fluctuations in the parameter signal and quantifying the parameter signal in real-time.

36. The optical fiber-based monitoring method according to claim 35, wherein the parameter associated with the SMS fiber structure is H₂ concentration, and wherein the parameter sensitive sensing material includes a nanocomposite coating layer comprising metallic nanoparticles in a porous dielectric matrix.

37. The optical fiber-based monitoring method according to claim 36, wherein the porous dielectric matrix is a porous polymer or a metal organic framework (MOF).

38. The optical fiber-based monitoring method according to claim 36, wherein the metallic nanoparticles include precious/noble metal nanoparticles.

39. The optical fiber-based monitoring method according to claim 38, wherein the nanoparticles are Pd, Pt, Au, or Ag nanoparticles.

40. The optical fiber-based monitoring method according to claim 35, wherein the parameter associated with the SMS fiber structure is magnetic field strength, and wherein the parameter sensitive sensing material includes a nanocomposite coating layer comprising colloidal single domain magnetic nanoparticles dispersed in a liquid carrier.

41. The optical fiber-based monitoring method according to claim 40, wherein the colloidal single domain magnetic nanoparticles are Fe3O4 or γ-Fe2O3.

42. The optical fiber-based monitoring method according to claim 40, wherein the liquid carrier is kerosene, heptane, or water.

43. The optical fiber-based monitoring method according to claim 40, wherein the colloidal single domain magnetic nanoparticles are dispersed in the liquid carrier with the aid of a surfactant for homogeneous dispersion.

44. The optical fiber-based monitoring method according to claim 43, wherein the surfactant is oleic acid or lauric acid.

45. The optical fiber-based monitoring method according to claim 35, wherein the parameter associated with the SMS fiber structure is magnetic field strength, and wherein the parameter sensitive sensing material includes a magneto-optical material, a magnetoresistive material, or a magnetostrictive material.

46. The optical fiber-based monitoring method according to claim 25, wherein the first light signal a single wavelength signal.

47. The optical fiber based monitoring method according to claim 25, further comprising positioning each of the SMS fiber structures at a distinct location to allow for quasi-distributed measurement both temporally and in a spatially distributed manner.

48. The optical fiber-based monitoring system according to claim 4, wherein each of a number of the plurality of multimode interferometric fiber structures is of unique construction and/or functionalization in order to realize a multiparameter sensing array.
